(19) United States
(12) Patent Application Publication
(10) Pub. No.: US 2008/0197378 A1
(43) Pub. Date: Aug. 21, 2008

(54) Group III Nitride Diodes on Low Index Carrier Substrates

(76) Inventors: Hua-Shuang Kong, Cary, NC (US); John A. Edmond, Cary, NC (US)

Correspondence Address: SUMMA, ALLAN & ADDITON, P.A., 11610 NORTH COMMUNITY HOUSE ROAD, SUITE 200, CHARLOTTE, NC, 28277, US

(21) Appl. No.: 11/676,715

(22) Filed: Feb. 20, 2007

(51) Int. Cl. H01L 33/00; H01L 29/22

(52) U.S. Cl. 257/103; 438/46; 257/E33.001; 257/98

(57) ABSTRACT

A light emitting diode is disclosed that includes a layer of p-type Group III nitride and a layer of n-type Group III nitride on a transparent carrier substrate that has an index of refraction lower then the layer of Group III nitride adjacent the carrier substrate. A layer of transparent adhesive joins the transparent substrate to the Group III nitride layers, and the transparent adhesive has an index of refraction lower than the layer of Group III nitride. The diode includes respective ohmic contacts to the p-type Group III nitride layer and to the n-type Group III nitride layer.

### BACKGROUND

The present invention relates to light emitting diodes, and in particular relates to light emitting diodes (LEDs) that are used in conjunction with a phosphor that converts light from the LED to produce an output that is either partially or totally a combination of the frequencies emitted by the LED and those converted by the phosphor.

Light emitting diodes are a class of photonic devices in which the application of current across the device, and most fundamentally across a p-n junction, generates recombination events between electrons and holes. In turn the events produce at least some energy in the form of emitted photons.

Because the recombination events are defined and constrained by the principles of quantum mechanics, the energy (and thus the photon) generated by the event depends upon the characteristics of the semiconductor material in which the event takes place. In this regard, the bandgap of the semiconductor material is the most fundamental characteristic with respect to the performance of light emitting diodes. Because the recombination events take place between the valence band and the conduction band of the semiconductor materials, they can never generate an amount of energy larger than the bandgap. Accordingly, materials with smaller bandgaps produce lower energy (and thus lower frequency) photons while materials with larger bandgaps can produce higher energy, higher frequency photons.

Light emitting diodes share a number of the favorable characteristics of other semiconductor devices. These include generally robust physical characteristics, long lifetime, high reliability, and, depending upon the particular materials, generally low cost.

Light emitting diodes, or at least the light emitting properties of semiconductors, have been recognized for decades. A 1907 publication (H. J. Round, Electrical World 49, 309) reported that current applied through silicon carbide produced an observed but unexplained emission of light. More widespread commercial use of LEDs began in the 1970s with indicator type use that incorporated lower frequency LEDs (typically red or yellow in color) formed from smaller bandgap materials such as gallium phosphide (GaP) and gallium arsenide phosphide (GaAsP).

In the 1990s, the development of the blue light emitting diode as a commercial rather than theoretical reality greatly increase the interest in LEDs for illumination purposes. In this regards, “indication” refers to a light source that is viewed directly as a self-luminous object (e.g. an indicator light on a piece of electronic equipment) while “illumination” refers to a source used to view other objects in the light reflected by those objects (e.g., room lighting or desk lamps). See, National Lighting Product Information Program, http://www.lrc.rpi.edu/programs/NLPIP/glossary.asp (December 2006).

Although light emitting diodes have become widely adapted for indicator purposes, their potential use for illumination includes applications such as indoor and outdoor lighting, backlighting (e.g. for displays), portable lighting (e.g., flashlights), industrial lighting, signaling, architectural and landscaping applications, and entertainment and advertising installations.

The availability of blue light emitting diodes correspondingly provides the opportunity for at least two techniques for producing white light. In one technique, blue LEDs are used in conjunction with red and green LEDs so the combination can form white light or—such as in a full-color display—any other combination of the three primary colors.

In a second technique, and one that has become commercially widely adopted, a blue light emitting diode is combined in a lamp with a yellow-emitting phosphor; i.e., a phosphor that absorbs the blue light emitted by the LED and converts and emits it as yellow light. The combination of blue and yellow light will produce a tone of white light that is useful for many illumination circumstances.

Although the terminology is used flexibly, the word “diode” (or “light emitting diode”) is most properly applied to the basic semiconductor structure that includes the p-n junction. The term “lamp” most properly refers to a packaged device in which the diode is mounted on electrodes that can connect it to a circuit and within a polymer lens that both protects the diode from environmental exposure and helps increase and direct the light output. Nevertheless, the term “LED” is often used to refer to packaged diodes that might more correctly be referred to as lamps and vice versa. Generally speaking the meaning of the terms will be clear in context.

Because the blue frequencies represent the highest energy within the visible spectrum (with red frequencies being the lowest), they must be produced by relatively high-energy recombination events. This in turn requires that the semiconductor material have a relatively wide bandgap. Accordingly, candidate materials for blue light emitting diodes, and thus for white-emitting LED lamps, include silicon carbide (SiC), the Group III nitrides (e.g., GaN), and diamond. Because of their direct emitter properties, most interest in blue light emitting diodes has focused upon the Group III nitride materials such as gallium nitride, aluminum gallium nitride (AlGaN), and indium gallium nitride (InGaN).

Illumination, however, tends to require higher quantities of light output than does indication. In this regard, the number of individual photons produced by a diode in any given amount of time depends upon the number of recombination events being generated in the diode, with the number of photons generally being less than the number of recombination events (i.e., not every event produces a photon). In turn, the number of recombination events depends upon the amount of current applied across the diode. Once again the number of recombination events will typically be less than the number of electrons injected across the junction. Thus, these electronic properties can reduce the external output of the diode.

Additionally, when photons are produced, they must also actually leave the diode and the lamp to be perceived by an observer. Although the majority of photons will leave the lamp without difficulty, a number of well-understood factors come into play that prevent the photons from leaving and that can thus reduce the external output of an LED lamp. These include internal reflection of a photon until it is re-absorbed rather than emitted. The index of refraction between the materials in the diode can also change the direction of an emitted photon and cause it to strike an object that absorbs it. The same results can occur for yellow photons that are emitted by the phosphor. In an LED lamp such “objects” can include the substrate, parts of the packaging, the metal contact layers, and any other material or element that prevents the photon from escaping the lamp.

Furthermore, in addition to emitting light, the epitaxial layers also absorb incoming light (and for some of the same quantum mechanic reasons). Thus from a general and comparative standpoint, a quantum well will re-absorb more light than a p-type epitaxial layer of gallium nitride, and a p-type layer of gallium nitride will re-absorb more light than an n-type epitaxial layer of gallium nitride.

To date, bulk crystal growth of large Group III nitride crystals remains difficult. Accordingly, in order to form the thin, high quality epitaxial layers that produce p-n junctions in LEDs, the Group III nitride materials must typically be grown on a substrate. When, as in some constructions, the substrate remains as part of the eventual light emitting lamp, it can provide one more opportunity to absorb photons emitted by the junction, thus reducing the external quantum efficiency of the overall diode.

The lens or encapsulant portion of most diode packages are typically formed of a low index epoxy resin, but these resins are generally subject to degradation in the presence of the higher frequency emissions of Group III nitride-based diodes. Additionally, a number of packages presently include a mirror layer (for example commonly assigned and co-pending application Ser. No. 11/082,470 filed Mar. 17, 2005 and now published as No. 20060060874) which in turn creates a more specular emission. Where a Lambertian pattern is desired, some type of diffuser must be included to reduce the specular character of the mirror. The presence of the diffuser, however, lowers the overall efficiency of the diode lamp. Furthermore, substrates that are generally convenient for manufacturing the diodes tend to be “dark”; i.e., they absorb a certain percentage of the photons produced by the diode. Such absorption similarly reduces the external quantum efficiency of a diode lamp.

Light emitting diodes typically include multiple layers of different materials. As a result, light emitted from the active portion must typically pass through or across one or more of such layers before exiting the diode. Additionally, when the diode is packaged as a lamp, the light leaving the diode must travel into, through, and out of the lens material. In each of these circumstances, Snell's law dictates that the photons will be refracted as they pass from one material to the next. The amount that the photons are refracted will depend upon the difference between the refractive indexes of the two materials and the angle of incidence at which the light strikes the interface.

In a diode or a diode lamp, although some reflected light will still escape the diode at some other location, a certain percentage will be totally internally reflected, never escape the diode or the lamp, and will thus functionally reduce the external quantum efficiency of the diode and of any lamp that includes the diode. Although the individual reduction in the percentage of photons escaping may appear to be relatively small, the cumulative effect can be significant and diodes that are otherwise very similar can have distinctly different performance efficiencies resulting from even these small percentage losses.

Accordingly, a continuing need exists to increase the external efficiency of light emitting diode and diode lamps.

### SUMMARY

In one aspect the invention is a light emitting diode that includes a layer of p-type Group III nitride and a layer of n-type Group III nitride on a transparent carrier substrate that has an index of refraction lower then the layer of Group III nitride adjacent said carrier substrate and respective ohmic contacts to the p-type Group III nitride layer and to the n-type Group III nitride layer.

In yet another aspect, the invention is a method of forming a light emitting diode. The method includes the steps of forming respective p-type and n-type layers of Group III nitride on a compatible substrate, separating the compatible substrate from the Group III nitride epitaxial layers, and joining the Group III nitride epitaxial layers to a transparent carrier substrate that has an index of refraction lower than the index of refraction of the adjacent Group III nitride layer.

In yet another aspect, the invention is a light emitting diode lamp that includes a reflector and a light emitting diode on the reflector. The diode includes at least respective layers of n-type and p-type Group III nitride on a transparent carrier substrate that has a refractive index lower than the refractive index of the adjacent Group III nitride layer. An encapsulant covers the light emitting diode and the encapsulant has a refractive index within 0.2 of the refractive index of the transparent carrier substrate.

The foregoing and other objects and advantages of the invention and the manner in which the same are accomplished will become clearer based on the followed detailed description taken in conjunction with the accompanying drawings.

### BRIEF DESCRIPTION OF THE DRAWINGS

FIGS. 1 through 5 are schematic cross-sectional diagrams of a light emitting diode in a first embodiment of the invention.

FIGS. 6 and 7 are schematic cross-sectional diagrams of a second embodiment of a light emitting diode according to the present invention.

FIG. 8 is a cross-sectional schematic diagram of an LED lamp according to the present invention.

### DETAILED DESCRIPTION

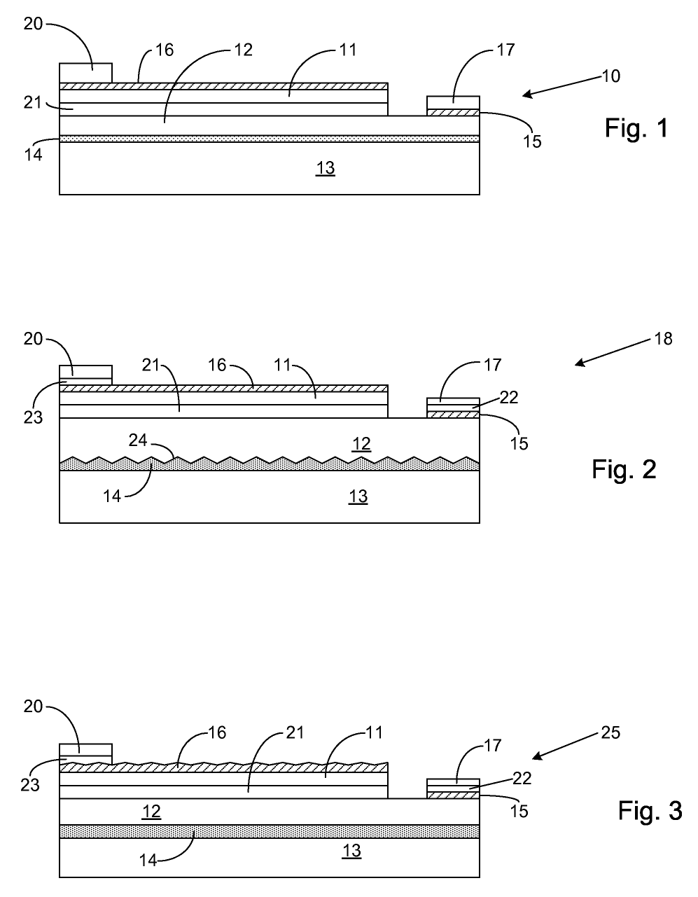

The present invention is a light emitting diode, a first embodiment of which is broadly designated at 10 in FIG. 1. In a basic embodiment, the diode can includes a layer of p-type Group III nitride 11 and a layer of n-type Group III nitride 12 on a transparent carrier substrate 13 that has an index of refraction lower than the layer of Group III nitride (which is the n-type layer 12 in FIG. 1) adjacent carrier substrate 13.

The low refractive index transparent carrier substrate typically has a refractive index of between about 1.35 and 1.65. Representative materials useful for diode carrier substrates include, but are not limited to, quartz, fused quartz, and glass. Sapphire can also be used as the transparent carrier substrate but has a slightly higher refractive index of about 1.8. The term “transparent” is generally well understood in this art, but representative transparent carrier substrates will transmit at least about 70 percent of incident light and preferably between about 90 and 100 percent of incident light of the relevant frequencies generated by the active portions of the diode.

Stated differently, by matching the refractive index of the substrate to the refractive index of the encapsulant, the invention enhances the transmission of light from the substrate to the encapsulant and thus enhances the external quantum efficiency.

Conventionally, amorphous materials such as glass have been considered less favorable for growth of epitaxial layers, and as a result conventional thought avoided using glass as a growth substrate for epitaxial layers. If desired, and provided the materials are otherwise compatible with the structure and function of the other elements of the invention, the carrier substrate can include phosphors or other particles, such as those included to favorably scatter or diffuse light. Furthermore, although described herein as a single element, it will be understood that the carrier substrate is not limited to a single layer, and could be a multilayer structure provided it meets the structural and functional requirements of the invention.

In exemplary embodiments of the invention, however, and as will be discussed later herein with respect to the method of manufacturing, the substrate does not represent the substrate upon which the layers of 11 and 12 are grown. Instead, a carrier 13 substrate having the desired optical properties is joined to the epitaxial layers 11, 12 by a low refractive index transparent adhesive schematically illustrated as the layer 14.

As used herein, the term “carrier substrate” refers to a substrate other than the one on which the epitaxial layers were originally grown. As is known to those familiar with the art, semiconductor epitaxial layers are best grown on compatible substrates that are most amenable for such growth. Typical factors include a good lattice match, coefficient of thermal expansion, chemical compatibility between the growth substrate and the epitaxial layers, and stability at chemical vapor deposition (CVD) growth temperatures.

For a number of reasons, once the epitaxial layers are grown, they can be removed from the growth substrate and placed on a carrier substrate. Such reasons include, but are not limited to, the desire to have a substrate in the final structure that has a more desired index of refraction than did the growth substrate.

In flip chip embodiments (i.e., those in which the substrate forms the emitting face of the final diode) or in embodiments where the growth substrate is replaced with the carrier substrate, some of the growth substrate can remain as a residue adjacent one of the epitaxial layers, but normally does not. In other cases, the carrier substrate can be the same material as the growth substrate, but added to the epilayers after the growth substrate has been removed.

The low index transparent adhesive that joins the carrier substrate to the active portions of the diode (typically the epitaxial layers) has a refractive index of between about 1.35 and 1.65, is photochemically stable with respect to electromagnetic radiation in the ultraviolet, blue, and green portions of the spectrum, and is thermally stable at temperatures of at least about 100° C.

Adhesives meeting this criteria, and that likewise avoid any undesired reactions with, or negative effect upon, the other portions of the diode are acceptable for joining the carrier substrate 13 to the epitaxial layers 11 and 12. One set of materials that meet this criteria include polysiloxane compositions, which are often referred to as “silicones.” Polysiloxanes have high optical transmittance in the UV and high energy visible region, can be tailored to have a desired refractive index within a range of about 1.38-1.62, have excellent photo-thermal stability, can be cured in a variety of techniques making processing easy, are available in high purity, and can be cured over a range of hardness from gels to hard resins. Such polysiloxanes are available from numerous sources and are generally well understood in the art and will not be otherwise described in detail herein.

Other candidate materials for the adhesive include the bisbenzocyclobutene-based (“BCB”) resins, examples of which are available under the CYCLOTENE brand from Dow Chemical, Midland, Mich. 48674, USA. These BCB resins are formulated as high-solids, low-viscosity solutions and have favorable electronic and mechanical properties. In the visible wavelengths they have a refractive index ranging from about 1.62 (at 400 nanometers) to about 1.55 (at 800 nanometers). They accordingly tend to match well with the transparent carrier substrates described herein.

The diode 10 represents an embodiment in which the n-type layer 12 is adjacent to the carrier substrates 13. This positions the p-type layer 11 closer to the face of the diode 10. Accordingly the ohmic contact to the n-type 12 is designated at 15 and the ohmic contact to the p-type layer 11 is designated at 16. Each of the ohmic contacts may include a respective bond pad 17 and 20, because in many circumstances, the metals that makes the best ohmic contacts are different from the metals that make the best contact to the remainder of the circuit or other devices.

In exemplary embodiments, the diode 10 further includes an active portion such as a multiple quantum well 21, or another emitting structure such as a single or double heterostructure. These structures are generally well understood in the art and will not be described further herein in detail.

In exemplary embodiments the p-type layer 11 and the n-type layer 12 are formed of gallium nitride (GaN) and the multiple quantum well 21 is formed of alternating layers of gallium nitride and indium gallium nitride (InGaN). As is well understood in the art, adjusting the atomic fraction of indium in InGaN (i.e., InₓGa₁₋ₓN) can tailor emission frequency of the diode to a certain extent, a factor that in practice is balanced against the tendency of increasing amounts of indium to form less stable nitrides.

Because p-type gallium nitride tends to be more resistive than n-type gallium nitride, the ohmic contact 16 to the p-type layer 11 is generally relatively large in order to enhance current flow through the p-type layer 11. Because the contact 16 is relatively large, in the invention it is formed to have a transmittance of at least about 70 percent and preferably as high as 90-100 percent. Accordingly, metal oxide compounds such as indium tin oxide (ITO) are useful for this purpose. As used herein transmittance refers to the difference, expressed as a percent, between the intensity of light that strikes an object and the intensity of the light that emerges after the original light passes through the object.

FIGS. 2 through 5 illustrate additional features of embodiments in which the n-type layer 12 is adjacent to the low index transparent carrier substrate 13. Where appropriate, like elements in different drawings will still carry like reference numerals.

FIG. 2 illustrates an embodiment that includes a lenticular surface 24 or interface between the n-type layer 12 and the adhesive layer 14. Additionally, either of the ohmic contacts 15 or 16, or the bond pads 17 or 20, can include a reflective surface 22 or 23 adjacent the ohmic contacts 15 or 16 for reflecting light away from the bond pad and preventing the bond pad 17 or 20 from absorbing light.

Of all of the items in the diode that tend to absorb light and thus reduce external quantum efficiency, the bond pads represent the highest absorption. Accordingly, even though in most circumstances reflecting light back into the epitaxial layers is undesired, the epitaxial layers will allow more light to escape then will the bond pads. As a result, reflecting light from the bond pads is almost always preferable, even if the reflected light returns to the epitaxial layers.

The term “lenticular” is used in a relatively broad sense to include carefully patterned surface features such as those set forth in commonly assigned and co-pending applications Publication No. 20060060874 and Ser. No. 11/461,018, filed Jul. 31, 2006 for “Method of Forming 3D Features for Improved Light Extraction,” as well as the more randomly generated features described in commonly assigned and co-pending application Ser. No. 11/343,180 filed Jan. 30, 2006 and published as No. 20060186418. The contents of each of these applications are incorporated entirely herein by reference.

Generally speaking, light tends to travel more readily from a lower index material to a higher index material. Accordingly, it can be counterintuitive to expect the light to go from a high index materials such as a Group III nitride layer to a lower index material such as the carrier substrate.

For this reason, a lenticular surface or interface (whether geometrically structured or chemically developed) tends to offer a greater advantage when light travels from a higher index material to a lower index material. Although not disadvantageous, the lenticular surface has less of a noticeable effect when the refractive index of the material on each side of the interface is about the same or when the light is traveling from a low index material to a high index material. Thus, in general the lenticular interface enhances the transmission of light from a higher refractive index material to a lower refractive index material and as a result is almost always preferred between the Group III nitride epitaxial layers and the low index of refraction carrier substrate.

Accordingly, the invention provides the opportunity to enhance the movement of light across a high-to-low interface by using the lenticular surface at positions that are most favorable toward the desired light extraction. This can, of course depend upon a number of design factors including packaging. Thus, the favorable positions for lenticular surfaces are not absolute, but rather are selected to enhance the light extraction from a given diode in a given circumstance.

The invention is not limited to the incorporation of the lenticular surface, however, because matching the index of refraction of the carrier substrate to that of the encapsulant, standing alone, has benefit. Stated in partial summary, enhancing the movement of light from the epitaxial layers to the transparent substrate (e.g., with a lenticular surface) enhances the external efficiency of the diode. Matching the index of refraction of the substrate to the index of refraction of the encapsulant (lens) likewise enhances the movement of light from the substrate to the encapsulant and thus enhances the external efficiency of the diode. Doing both—i.e., increasing the movement of light from the epitaxial layers to the substrate and matching the refractive indices of the substrate and the encapsulant-further enhances the external efficiency of the diode.

FIG. 3 illustrates an embodiment broadly designated at 25 in which the ohmic contact 16 to the p-type layer 11 carries the lenticular surface.

FIG. 4 illustrates an embodiment of the diode broadly designated at 27 in which both the ohmic contact 16 and the p-type layer 11 carry the lenticular pattern. FIG. 4 also illustrates that in any of these embodiments, the surface 26 of the carrier substrate 13 opposite from the epitaxial layers 11 and 12 can likewise carry a lenticular pattern. In a similar manner, and although not specifically illustrated in FIG. 4, the top surface of the substrate 13 can likewise include a lenticular surface.

FIG. 5 illustrates another embodiment of the diode broadly designated 30 in which the ohmic contact 16 to the p-type layer 11 has a planar surface forming the face of the diode, but with a lenticular interface between the ohmic contact 16 and the p-type layer 11.

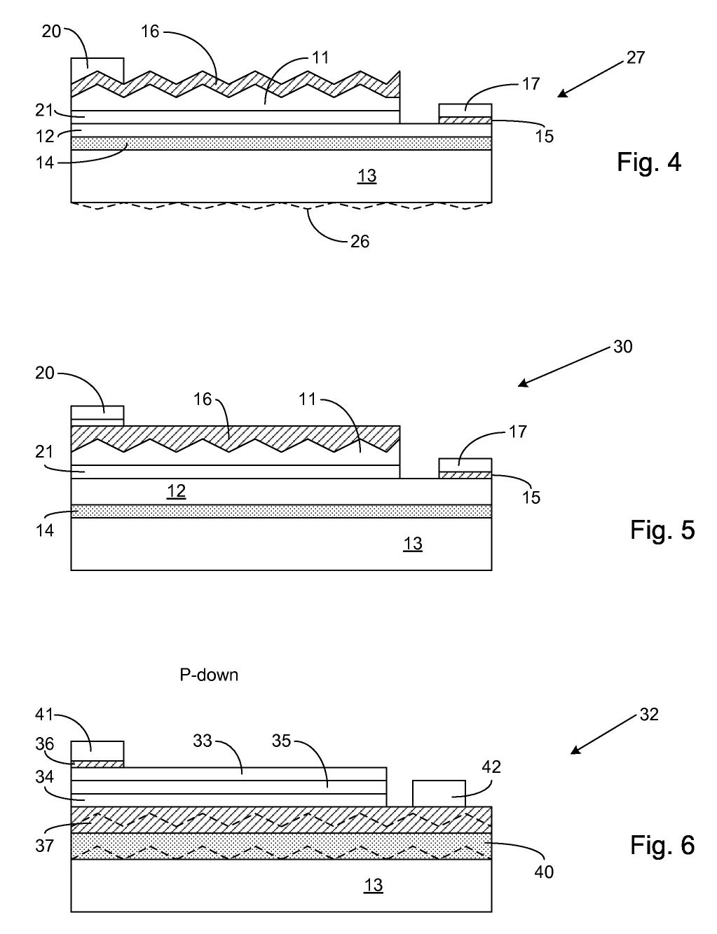

FIGS. 6 and 7 illustrates an alternative embodiment of the invention in which the p-type layer is on the low index transparent carrier substrate. As a point of description, as used herein the term “on” refers to the relationship between layers and does not necessarily limit the layers to be in direct contact. Thus, in some contexts, the word “on” can also mean “above” or “adjacent.” In any case, the meaning will generally be clear in context.

Accordingly, FIG. 6 illustrates a diode broadly designated at 32. The n-type layer 33 forms the face of the diode 32 and the p-type layer 34 is on the low index transparent carrier substrate which is again designated at 13. FIG. 6 illustrates a multiple quantum well 35 and an ohmic contact 36 to the n-type layer 33 and a large (for reasons explained previously) ohmic contact 37 to the p-type layer 34. FIG. 6 also illustrates the low index of refraction adhesive layer 40 between the carrier substrate 13 and the epitaxial layer 33 and 34. Specifically, the adhesive layer 40 is positioned between the p-type contact 37 and the carrier substrate 13.

A first bond pad 41 covers the ohmic contact 36 to the n-type layer 33 and a second bond pad 42 is in contact with the p-type ohmic contact 37. FIG. 6 also illustrates (using the dotted lines) that the interface between the p-ohmic contact and the adhesive can be lenticular, or the interface between the adhesive and the carrier substrate 13 can be lenticular, or both interfaces can be lenticular.

FIG. 7 is another embodiment of a diode according to the invention illustrated at 44. FIG. 7 is similar to FIG. 6 in that the p-type layer 34 is closest to the transparent low index carrier substrate 13. In FIG. 7, the n-type layer 33 carries a lenticular surface 45. A multiple quantum well is again designated at 35 and the Group III nitride epitaxial layers 33, 34 are typically gallium nitride. FIG. 7 illustrates an embodiment in which both the interface between the p-type layer 34 and the ohmic contact 37 is lenticular and the interface between the ohmic contact 37 and the adhesive 40 is lenticular, essentially creating a lenticular profile for the ohmic contact 37.

As in the other embodiments, other portions of the device can also include lenticular surfaces in a manner described with respect to the other drawings.

FIG. 7 also illustrates the ohmic contact 36 to the n-type layer 33, the bond pad 41 to the ohmic contact 36 and the bond pad 42 to the ohmic contact 37.

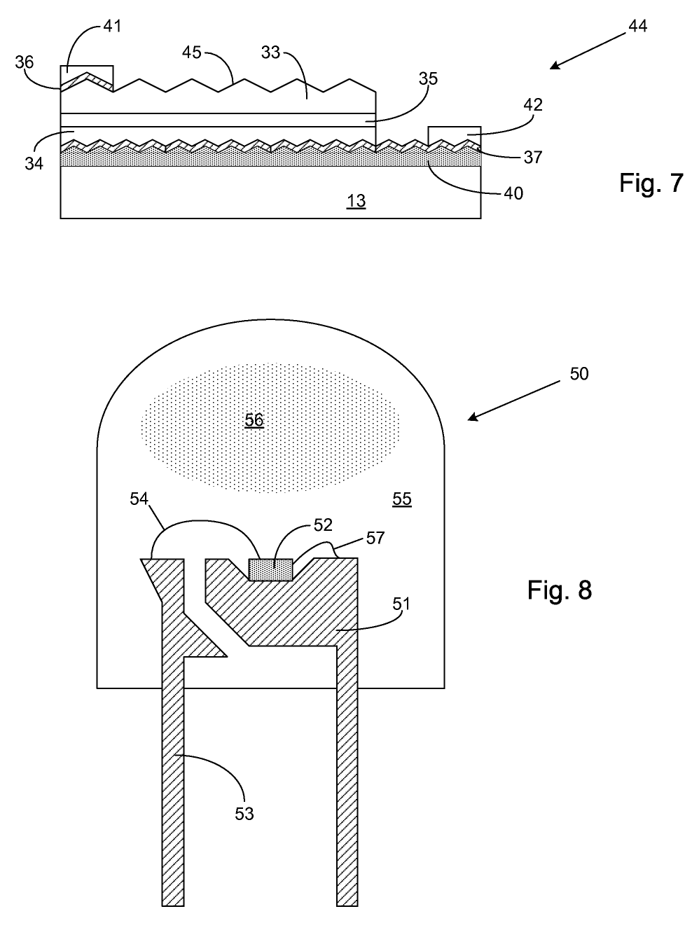

FIG. 8 illustrates the invention in the context of a light emitting diode lamp broadly designated at 50. The lamp includes a reflector 51 that forms one electrode to the light emitting diode 52 As in the other embodiments, the diode 52 includes the Group III nitride layers and the low refractive index transparent carrier substrate. A second electrode 53 and respective wires 54 and 57 complete an electrical connection to the diode 52 in a manner which is otherwise well understood in this art. An encapsulant lens 55 covers the light emitting diode 52 and typically the reflector 51 and electrode 53 as well. In this embodiment, the encapsulant 55 has a refractive index within 0.2 of the refractive index of the transparent carrier substrate. The polysiloxane compositions referred to earlier are also appropriate materials for the encapsulant 55.

FIG. 8 illustrates that in many typical embodiments for high-energy light emitting diodes, the lamp 50 will include a phosphor 56. In such embodiments, the Group III nitride materials in the diode 50 emit in the blue portion of the visible spectrum and the phosphor 56 is selected to emit in the yellow portion of the visible spectrum in response to the blue frequencies emitted by the diode 52. Cesium doped yttrium aluminum garnet (YAG) is generally favored for this purpose.

In FIG. 8 the phosphor 56 is schematically illustrated as the dotted ellipse 56 and is positioned generally above the diode 52. It will be understood, however, that the phosphor 56 can be positioned more precisely and that FIG. 8 is schematically rather than exactly representative of the phosphor location. Commonly assigned and co-pending application Ser. No. 60/824,385 filed Sep. 1, 2006 for “Phosphor Position in Light Emitting Diodes” describes additional positions into which the phosphor can be placed for advantageous purposes. The contents of this application is incorporated entirely herein by reference.

In yet another embodiment, the invention is a method of forming a light emitting diode. In this embodiment, the invention includes the steps of forming (typically by epitaxial growth) respective p-type and n-type layers of Group III nitride on a compatible substrate. Silicon carbide (SiC) is particularly useful as the compatible substrate because it has a closer lattice match to the Group III nitrides then do other substrates such as sapphire or silicon. The invention is not, however, limited to silicon carbide and if other substrate materials are advantageous for purposes other than lattice matching, they can be incorporated provided they do not otherwise interfere with the production of the diode or its function when complete.

Following growth of the epitaxial layers, the compatible substrate is removed from the Group III nitride epitaxial layers and then the Group III nitride epitaxial layers are joined to the transparent carrier substrate with the index of refraction lower than the index of refraction of the adjacent Group III nitride layer.

In exemplary embodiments, a low index transparent adhesive as described previously is used to join the carrier substrate to the epitaxial layers. The invention is not, however, limited to the use of low index adhesives, and other techniques can be used to join the carrier substrate to the epitaxial layers provided they are otherwise consistent with the structure and function of the invention.

As in the other embodiments, the transparent carrier substrate with the low index of refraction comprises a material selected from the group consisting of quartz, fused quartz, glass, and sapphire.

In order to produce the structures described herein, additional features such as multiple quantum wells, superlattices, or single or double heterostructures can be added between the steps of growing the respective p-type and n-type layers on the original compatible substrate.

In the drawings and specification there has been set forth a preferred embodiment of the invention, and although specific terms have been employed, they are used in a generic and descriptive sense only and not for purposes of limitation, the scope of the invention being defined in the claims.

1. A light emitting diode comprising a layer of p-type Group III nitride and a layer of n-type Group III nitride on a transparent carrier substrate that has an index of refraction lower then the layer of Group III nitride adjacent said carrier substrate;

2. A light emitting diode according to claim 1 further comprising a layer of transparent adhesive joining said transparent substrate to said Group III nitride layers, said transparent adhesive having an index of refraction lower than the layer of Group III nitride. and

3. A light emitting diode according to claim 2 wherein said transparent adhesive has a refractive index of between 1.35 and 1.65, is photochemically stable with respect to electromagnetic radiation in the ultraviolet, blue, and green portions of the spectrum, and is thermally stable at temperatures of at least about 100° C.

4. A light emitting diode according to claim 1 further comprising respective ohmic contacts to said p-type Group III nitride layer and to said n-type Group III nitride layer; and

5. A light emitting diode according to claim 3 further comprising an encapsulant with a refractive index within about 0.2 of the refractive index of said carrier substrate.

6. A light emitting diode according to claim 3 wherein said transparent adhesive comprises a polysiloxane adhesive.

7. A light emitting diode according to claim 3 wherein said transparent adhesive comprises a bisbenzocyclobutene-based resin.

8. A light emitting diode according to claim 1 wherein said transparent carrier substrate is selected from the group consisting of quartz, fused quartz, glass, and sapphire.

9. A light emitting diode according to claim 4 wherein said n-type Group III nitride layer is on said substrate and said p-type Group III nitride layer is on said n-type layer.

10. A light emitting diode according to claim 9 comprising a lenticular interface between said n-type layer and said carrier substrate.

11. A light emitting diode according to claim 9 wherein:
said n-type Group III nitride comprises gallium nitride;
said p-type Group III nitride comprises gallium nitride; and
said diode further comprises a Group III nitride active portion between said p-type gallium nitride layer and said n-type gallium nitride layer.

12. A light emitting diode according to claim 11 wherein said active portion is selected from the group consisting of quantum wells, multiple quantum wells, superlattices, single heterostructures and double heterostructures.

13. A light emitting diode according to claim 9 wherein said ohmic contact to said p-type gallium nitride layer has a transmittance of at least about 70 percent and covers a large portion of said p-type layer.

14. A light emitting diode according to claim 9 wherein said ohmic contact to said p-type gallium nitride layer has a transmittance of at about 90-100 percent and covers a large portion of said p-type layer.

15. A light emitting diode according to claim 9 wherein said ohmic contact to said p-type gallium nitride layer comprises indium tin oxide.

16. A light emitting diode according to claim 13 further comprising a first bond pad to said p-type ohmic contact and a second bond pad to said n-type ohmic contact.

17. A light emitting diode according to claim 16 wherein at least one of said bond pads has a reflective surface adjacent the ohmic contact for reflecting light from said bond pad and preventing said bond pad from absorbing light.

18. A light emitting diode according to claim 13 comprising a lenticular interface between said semi-transparent ohmic contact and said p-type Group III nitride layer.

19. A light emitting diode according to claim 9 comprising a lenticular surface on said low index transparent substrate opposite to the interface between said n-type Group III nitride layer and said low index transparent substrate.

20. A light emitting diode according to claim 9 wherein said p-type Group III nitride layer has a lenticular surface to increase light extraction and said ohmic contact substantially conforms to said lenticular surface.

21. A light emitting diode according to claim 9 wherein said semitransparent p-type ohmic contact has a lenticular surface opposite the interface between said p-type ohmic contact and said p-type gallium nitride layer.

22. A light emitting diode according to claim 9 that includes a lenticular surface selected from the group consisting of:
the interface between said Group III nitride layers and said low index transparent substrate;
the interface between said p-type ohmic contact and said p-type layer;
the surface of said p-type Group III nitride layer;
the surface of said n-type Group III nitride layer;
the surface of said p-type ohmic contact;
the surface of said substrate opposite said Group III nitride layers; and
combinations of these lenticular surfaces.

23. A light emitting diode comprising:
a layer of p-type Group III nitride on a carrier substrate that has a refractive index lower than the refractive index of said p-type Group III nitride;
a layer of n-type Group III nitride on said p-type Group III nitride layer;
a layer of transparent adhesive joining said transparent substrate to said Group III nitride layers, said transparent adhesive having an index of refraction lower than the layer of Group III nitride; an ohmic contact to said p-type Group III nitride layer; and
an ohmic contact to said n-type Group III nitride layer.

24. A light emitting diode according to claim 23 further comprising a bond pad to said p-type ohmic contact and a bond pad to said n-type ohmic contact.

25. A light emitting diode according to claim 23 wherein at least one of said ohmic contacts includes a reflective surface facing said low indexed transparent substrate.

26. A light emitting diode according to claim 23 wherein said adhesive has a refractive index of between 1.35 and 1.65.

27. A light emitting diode according to claim 23 wherein said adhesive comprises polysiloxane.

28. A light emitting diode according to claim 23 wherein said adhesive comprises a bisbenzocyclobutene-based resin.

29. A light emitting diode according to claim 23 wherein said p-type ohmic contact is semi-transparent.

30. A light emitting diode according to claim 23 wherein said p-type ohmic contact is indium tin oxide.

31. A light emitting diode according to claim 29 wherein said p-type ohmic contact is positioned between said p-type Group III nitride layer and said low index transparent adhesive covers substantially all of said p-type Group III nitride layer.

32. A light emitting diode according to claim 23 wherein:
said ohmic contact to said p-type layer is between said p-type layer and said low index transparent substrate; and
said p-type ohmic contact has a lenticular surface adjacent said low index transparent substrate.

33. A light emitting diode according to claim 23 wherein said n-type Group III nitride layer forms the face of said diode and said n-type Group III nitride layer has a lenticular surface for increasing light extraction.

34. A light emitting diode according to claim 23 wherein:
said p-type layer has a lenticular surface facing said low index transparent substrate;
said low index transparent adhesive has a lenticular surface opposite said low index transparent substrate; and
said p-type ohmic contact is between said p-type layer and said low index transparent adhesive and conforms to each of said respective lenticular surfaces.

35. A light emitting diode according to claim 23 that includes a lenticular surface selected from the group consisting of:
the surface of said n-type layer opposite said low index transparent substrate;
the interface between said low index transparent substrate and said epitaxial layers;
the surface of said low index transparent substrate opposite said epitaxial layers;
the surface of said p-type Group III nitride layer adjacent said p-type ohmic contact; and
combinations of these lenticular surfaces.

36. A light emitting diode according to claim 23 wherein said n-type Group III nitride comprises gallium nitride;
said p-type Group III nitride comprises gallium nitride; and
said diode further comprises a Group III nitride active portion between said p-type gallium nitride layer and said n-type gallium nitride layer.

37. A light emitting diode according to claim 36 wherein said active portion is selected from the group consisting of quantum wells, multiple quantum wells, superlattices, single heterostructures and double heterostructures.

38. A method of forming a light emitting diode comprising:
forming respective p-type and n-type layers of Group III nitride on a compatible substrate;
separating the compatible substrate from the Group III nitride epitaxial layers; and
joining the Group III nitride epitaxial layers to a transparent substrate that has an index of refraction lower than the index of refraction of the adjacent Group III nitride layer.

39. A method according to claim 38 further comprising joining the transparent substrate to the epitaxial layers with a low index transparent adhesive.

40. A method according to claim 38 wherein the step of joining the epitaxial layers to the transparent substrate comprises joining the layers to a substrate selected from the group consisting of quartz, fused quartz, glass, and sapphire.

41. A method according to claim 38 further comprising adding a multiple quantum well structure between the p-type and n-type Group III nitride layers prior to removing the compatible substrate from the layers.

42. A method according to claim 38 comprising growing respective p-type and n-type layers of gallium nitride on the compatible substrate.

43. A method according to claim 42 comprising growing the respective p-type and n-type layers of gallium nitride on a silicon carbide substrate.

44. A method according to claim 39 comprising joining the substrate to the epitaxial layers with a transparent adhesive that has an index of refraction of between about 1.35 and 1.6.

45. A method according to claim 39 comprising joining the substrate to the epitaxial layers with a polysiloxane adhesive.

46. A method according to claim 39 comprising joining the substrate to the epitaxial layers with a bisbenzocyclobutene-based adhesive.

47. A light emitting diode lamp comprising:
a light emitting diode including at least respective layers of n-type and p-type Group III nitride on a transparent carrier substrate that has a refractive index lower than the refractive index of the adjacent Group III nitride layer;
a transparent adhesive between said Group III nitride layers and said transparent carrier substrate, said transparent adhesive having an index of refraction lower than the refractive index of the adjacent Group III nitride layer; and
an encapsulant covering said light emitting diode, said encapsulant having a refractive index within 0.2 of the refractive index of said transparent substrate.

48. A light emitting diode lamp according to claim 47 wherein said diode is positioned on a reflector.

49. A light emitting diode lamp according to claim 47 wherein said encapsulant has a refractive index within 0.1 of the refractive index of said transparent substrate.

50. A light emitting diode lamp according to claim 47 wherein said encapsulant has a refractive index greater than the refractive index of said transparent substrate.

51. An LED lamp according to claim 47 further comprising a phosphor in said encapsulant.

52. An LED lamp according to claim 51 wherein said phosphor comprises cesium-doped YAG.

53. An LED lamp according to claim 47 wherein said transparent substrate has a refractive index between 1.35 and 1.65.

54. An LED lamp according to claim 47 wherein said transparent adhesive has an index of refraction of between 1.35 and 1.65.

55. An LED lamp according to claim 54 wherein said transparent adhesive is selected from the group consisting of polysiloxane adhesives and bisbenzocyclobutene-based adhesives.
